(19) United States
(12) Patent Application Publication
(10) Pub. No.: US 2026/0304661 A1
(43) Pub. Date: Oct. 1, 2026

(54) ELECTRONIC DEVICE MANUFACTURING EQUIPMENT, ELECTRONIC DEVICE MANUFACTURED BY THE SAME, AND METHOD OF MANUFACTURING THE ELECTRONIC DEVICE

(71) Applicant: Samsung Display Co., LTD., Yongin-si (KR)

(72) Inventors: JONGSUK LEE, Yongin-si (KR); KWAN BAE KONG, Yongin-si (KR); HYUNSANG PARK, Yongin-si (KR); WOORAM SEO, Yongin-si (KR); JIHOON SONG, Yongin-si (KR); JAE-YOUNG YU, Yongin-si (KR); JINYOUNG LEE, Yongin-si (KR); SEUNGJIN LIM, Yongin-si (KR); Yongseong JANG, Yongin-si (KR)

(21) Appl. No.: 19/555,122

(22) Filed: Mar. 3, 2026

(30) Foreign Application Priority Data
Mar. 25, 2025 (KR) 10-2025-0038339

(51) Int. Cl. H05K 5/03

(52) U.S. Cl. CPC H05K 5/03

(57) ABSTRACT

An electronic device manufacturing equipment includes an upper jig including a bottom surface and an accommodation groove defined by side surfaces bent and extending from the bottom surface, a lower jig disposed below the upper jig, and a pad disposed between the upper jig and the lower jig, wherein the pad includes a pressing surface facing the bottom surface, a rear surface facing the lower jig, and side pad surfaces bent from the rear surface toward the pressing surface, and the pressing surface includes a curved portion having a predetermined curvature in a cross-section, edge portions respectively connected to the side pad surfaces, and flat portions respectively connecting the curved portion and the edge portions and each including a flat surface.

This application claims priority to Korean Patent Application No. 10-2025-0038339, filed on Mar. 25, 2025, and all the benefits accruing therefrom under 35 U.S.C. § 119, the content of which in its entirety is herein incorporated by reference.

### BACKGROUND

### 1. Field

Embodiments of the disclosure described herein relate to electronic device manufacturing equipment, an electronic device manufactured using the manufacturing equipment, and a method of manufacturing the electronic device.

### 2. Description of the Related Art

A display device may include a window and a display panel. The window may be provided to protect the display panel, and the window and the display panel may be attached to each other by an adhesive layer. A lamination device may be used to laminate the window and the display panel.

### SUMMARY

Embodiments of the disclosure provide an electronic device manufacturing equipment including a pad for supporting precise compression between a display panel and a window, an electronic device manufactured using the manufacturing equipment, and a method of manufacturing an electronic device.

In an embodiment of the disclosure, an electronic device manufacturing equipment includes an upper jig including a bottom surface and an accommodation groove defined by side surfaces bent and extending from the bottom surface, a lower jig disposed below the upper jig, and a pad disposed between the upper jig and the lower jig, where the pad includes a pressing surface facing the bottom surface, a rear surface facing the lower jig, and side pad surfaces bent from the rear surface toward the pressing surface, and the pressing surface includes a curved portion having a predetermined curvature in a cross-section, edge portions respectively connected to the side pad surfaces, and flat portions respectively connecting the curved portion and the edge portions and each including a flat surface.

In an embodiment, each of the edge portions may have a predetermined curvature in the cross-section, and the predetermined curvature of the curved portion and the predetermined curvature of each of the edge portions may be different from each other.

In an embodiment, a radius of curvature of each of the edge portions may be smaller than a radius of curvature of the curved portion.

In an embodiment, the flat surface may be an inclined surface inclined with respect to the rear surface.

In an embodiment, a height of the inclined surface in the cross-section may be smaller than a radius of curvature of each of the edge portions.

In an embodiment, each of the side pad surfaces may include a curved surface having a predetermined curvature in the cross-section.

In an embodiment, the curved surface may be a concave surface.

In an embodiment, the curved surface may be connected to the edge portions.

In an embodiment, each of the side pad surfaces may include a portion protruding from the edge portions in the cross-section.

In an embodiment, the pressing surface may include a corner having a predetermined curvature in a plan view.

In an embodiment, the pad may be elastic.

In an embodiment of the disclosure, an electronic device manufacturing equipment includes an upper jig including a bottom surface and an accommodation groove defined by side surfaces bent and extending from the bottom surface, a lower jig disposed below the upper jig, and a pad disposed between the upper jig and the lower jig, where the pad includes a pressing surface including corners including four straight sides and four corner sides arranged between the straight sides and each connecting the straight sides next (adjacent) to each other in a plan view among the four straight sides, a rear surface, and a plurality of side pad surfaces each connecting the pressing surface and the rear surface, the pressing surface includes a curved portion having a convex curved surface toward the upper jig, and a plurality of connection portions connecting the curved portion and the side pad surfaces and defining the corners, and each of the connection portions includes a flat surface and a curved surface connecting the flat surface and the side pad surfaces.

In an embodiment, the connection portions may include straight connection portions defining the straight sides and corner connection portions defining the corner sides, and a curvature of each of the corner connection portions in the plan view may be smaller than a curvature of the curved surface in a cross-section.

In an embodiment, the flat surface may have an inclination with respect to the bottom surface in a cross-section, and a height of the inclination may be smaller than a radius of curvature of the curved surface.

In an embodiment, a side pad surface of the plurality of connection portions may include a concave surface.

In an embodiment, a curvature of a curved surface of each of the straight connection portions in the cross-section may be greater than a curvature of the curved portion.

In an embodiment of the disclosure, a method of manufacturing an electronic device includes an operation of fixing a window including a main transmissive surface and side transmissive surfaces bent and extending from the main transmissive surface in one direction to an upper jig including an accommodation groove, an operation of fixing a display panel including a rear surface of to which a guide film is attached to a clamp, an operation of providing a pad below the window and the display panel, the pad including a pressing surface, a rear surface, and side pad surfaces connecting the rear surface and the pressing surface, and an operation of compressing the bent display panel and the window by applying pressure to the pad in a direction toward the display panel, where the pressing surface includes a curved portion having a predetermined curvature in a cross-section, edge portions respectively connected to the side pad surfaces, and flat portions connecting the curved portion and the edge portions and each including a flat surface, and in the operation of providing the pad below the window and the display panel, the flat portions are aligned to overlap the side transmissive surfaces, respectively.

In an embodiment, the operation of compressing the display panel and the window may include a first compression operation of compressing portions of the window and the display panel by applying pressure to the curved portion and a second compression operation of compressing other portions of the window and the display panel by applying pressure to the pressing surface except for the curved portion.

In an embodiment, in the first compression operation, the flat portions may not contact the guide film.

In an embodiment of the disclosure, an electronic device includes a display panel and a window disposed on the display panel, where the display panel and the window include an upper jig including a bottom surface and an accommodation groove defined by side surfaces bent and extending from the bottom surface, a lower jig disposed below the upper jig, and a pad disposed between the upper jig and the lower jig, the pad includes a pressing surface facing the bottom surface, a rear surface facing the lower jig, and side pad surfaces bent from the rear surface toward the pressing surface, and the pressing surface includes a curved portion having a predetermined curvature in a cross-section, edge portions connected to the side pad surfaces, and flat portions connecting the curved portion and the edge portions and each including a flat surface.

### BRIEF DESCRIPTION OF THE DRAWINGS

The above and other embodiments, advantages and features of the disclosure will become apparent by describing in detail embodiments thereof with reference to the accompanying drawings.

FIG. 1 is a block diagram of an embodiment of an electronic device.

FIG. 2 is schematic views illustrating various electronic devices according to an embodiment.

FIG. 3 is a perspective view of an embodiment of a display device of the disclosure.

FIG. 4 is an exploded perspective view illustrating an embodiment of a partial configuration of the display device according to the disclosure.

FIG. 5 is a perspective view of an embodiment of a window of the disclosure.

FIG. 6 is a perspective view of an embodiment of the window of the disclosure.

FIG. 7A is a perspective view of an embodiment of electronic device manufacturing equipment of the disclosure.

FIGS. 7B and 7C are cross-sectional views of an embodiment of a configuration of the electronic device manufacturing equipment of the disclosure.

FIGS. 8A to 8D are cross-sectional views illustrating an embodiment of some of operations of a method of manufacturing an electronic device using the electronic device manufacturing equipment according to the disclosure.

FIGS. 9A and 9B are perspective views of an embodiment of a pad of the disclosure.

FIG. 9C is a plan view of an embodiment of the pad of the disclosure.

FIG. 9D is a cross-sectional view of an embodiment of the pad of the electronic device manufacturing equipment of the disclosure.

FIG. 10 is a schematic view illustrating a shape of a corner portion of each of the pads having different radii of curvature and a shape of a corner portion of a display panel.

FIG. 11 is a cross-sectional view of an embodiment of the pad of the disclosure.

FIG. 12A is an enlarged cross-sectional view of an embodiment of a partial area of the pad of the disclosure.

FIG. 12B is an enlarged cross-sectional view of an embodiment of the partial area of the pad of the disclosure.

FIGS. 13A to 13C are schematic views illustrating an embodiment of a deformed state of the pad in a process of compressing the display panel and the window using the pad according to the disclosure.

FIGS. 14A to 14C are schematic views illustrating an embodiment of a deformed state of the pad in a process of compressing the display panel and the window using the pad according to the disclosure.

FIG. 15A is a schematic view illustrating an embodiment of a deformed state of the pad in an embodiment of the disclosure in a lamination process of the display panel and the window.

FIG. 15B is a schematic view illustrating an embodiment of a deformed state of the pad in an embodiment of the disclosure in a lamination process of the display panel and the window.

### DETAILED DESCRIPTION

Since the disclosure is variously modified and has various forms, an embodiment thereof will be illustrated in the drawings and will be described herein in detail. However, it should be understood that the present disclosure is not limited to a specific disclosure and includes all changes, equivalents, and substitutes included in the spirit and scope of the disclosure.

In the specification, the expression that a first component (or an area, a layer, a part, a portion, etc.) is “disposed on”, “connected with” or “coupled to” a second component means that the first component is directly disposed on/connected with/coupled to the second component or means that a third component is interposed therebetween.

The same reference numerals refer to the same components. Further, in the drawings, the thickness, the ratio, and the dimension of components are exaggerated for effective description of technical contents. The term “and/or” includes all combinations of one or more components that may be defined by associated components.

Although the terms “first,” “second,” etc., may be used to describe various components, the components should not be limited by the terms. The terms are only used to distinguish one component from another component. For example, without departing from the right scope of the present disclosure, a first component may be referred to as a second component, and similarly, the second component may be also referred to as the first component. Singular expressions include plural expressions unless clearly otherwise indicated in the context.

Further, terms such as “below,” “under,” “on a lower side,” “above,” “on,” and “on an upper side” are used to describe the relationship between components illustrated in the drawings. The terms that are relative in concept are described based on a direction illustrated in drawings.

It will be understood that the terms “include”, “comprise”, “have”, etc. specify the presence of features, numbers, steps, operations, elements, or components, described in the specification, or a combination thereof, and do not exclude in advance the presence or additional possibility of one or more other features, numbers, steps, operations, elements, or components or a combination thereof.

In the specification, the wording “directly disposed” may mean that there is no layer, no film, no area, no plate, and the like added between a part such as a layer, a film, an area, and a plate, and other parts. For example, the wording “directly disposed” may mean that an additional member such as an adhesive member is not disposed between two layers or two members.

Unless otherwise defined, all terms (including technical terms and scientific terms) used in the specification have the same meaning as commonly understood by those skilled in the art to which the disclosure belongs. Further, terms such as terms defined in the dictionaries commonly used should be interpreted as having a meaning consistent with the meaning in the context of the related technology and should not be interpreted in overly ideal or overly formal meanings unless explicitly defined herein.

Hereinafter, a display device in an embodiment will be described with reference to the accompanying drawings.

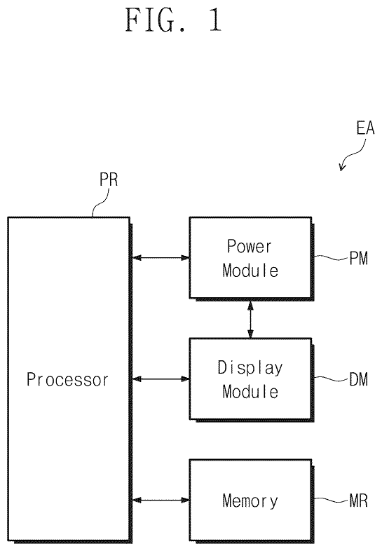

FIG. 1 is a block diagram of an embodiment of an electronic device.

Referring to FIG. 1, an electronic device EA in an embodiment may include a display module DM, a processor PR, a memory MR, and a power module PM.

The processor PR may include at least one of a central processing unit (“CPU”), an application processor (“AP”), a graphic processing unit (“GPU”), a communication processor (“CP”), an image signal processor (“ISP”), and a controller.

Data information desired for operating the processor PR or the display module DM may be stored in the memory MR. When the processor PR executes an application stored in the memory MR, an image data signal and/or an input control signal may be transmitted to the display module DM, and the display module DM may process the received signal and output image information through a display screen. The display module DM may include a display panel that displays an image.

The power module PM may include a power conversion module. The power conversion module may be a power supply module such as a power adapter or a battery device and convert power supplied by the power supply module to generate power desired for operating the electronic device EA.

At least one of components of the electronic device EA may be included in a display module in an embodiment, which will be described below, and a display device in an embodiment including the same. Further, some of individual modules functionally included inside one module may be included inside the display device, and remaining (the other) individual modules thereof may be provided separately from the display device. In an embodiment, the display device may include the display module DM, and the processor PR, the memory MR, and the power module PM may be provided in the form of other devices in the electronic device EA rather than the display device, for example.

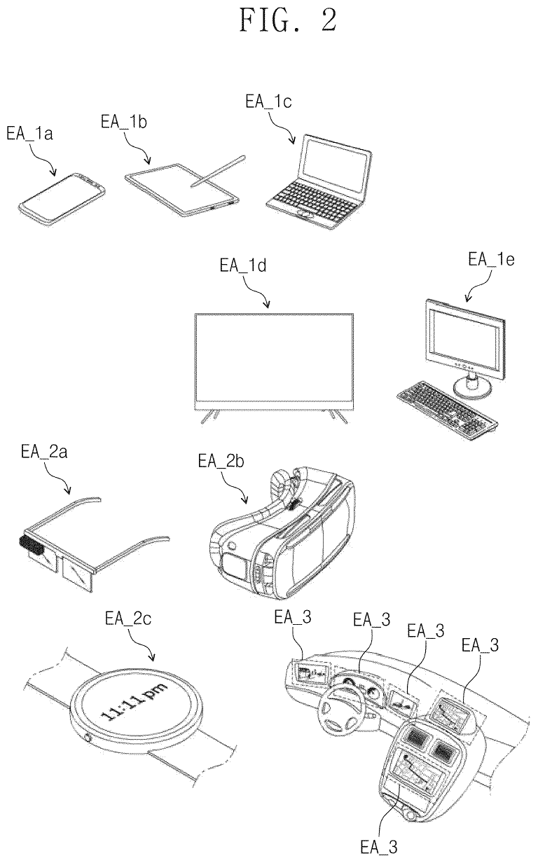

FIG. 2 is schematic views illustrating an embodiment of various electronic devices.

Referring to FIG. 2, various electronic devices including the display module in an embodiment may include an image display electronic device such as a smartphone EA_1a, a tablet personal computer EA_1b, a laptop computer EA_1c, a television (“TV”) EA_1d, and a desk monitor EA_1e, a wearable electronic device such as a smart glasses EA_2a, a head mounted display EA_2b, and a smart watch EA_2c, and a vehicle electronic device EA_3 such as an instrument panel, a center fascia, a center information display (“CID”) disposed on a dashboard, and a room mirror display of a vehicle.

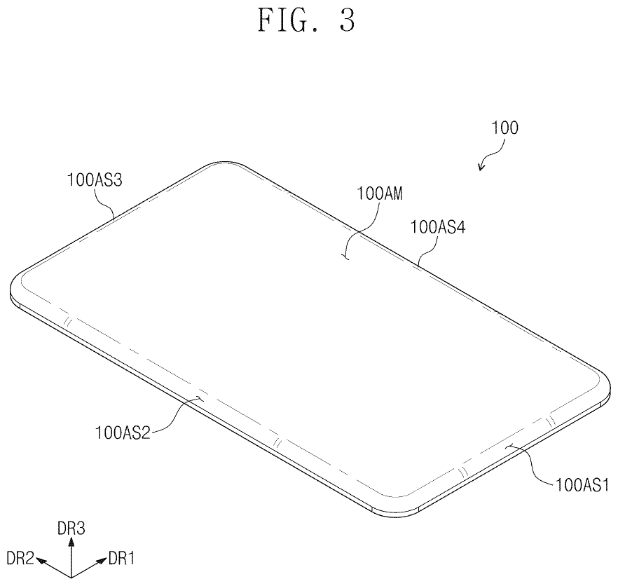

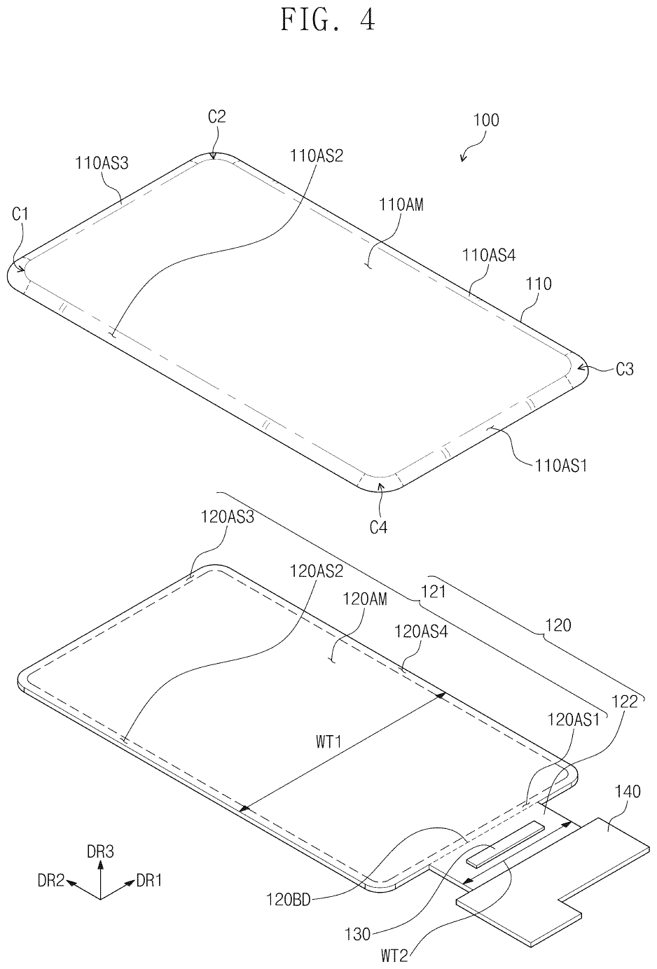

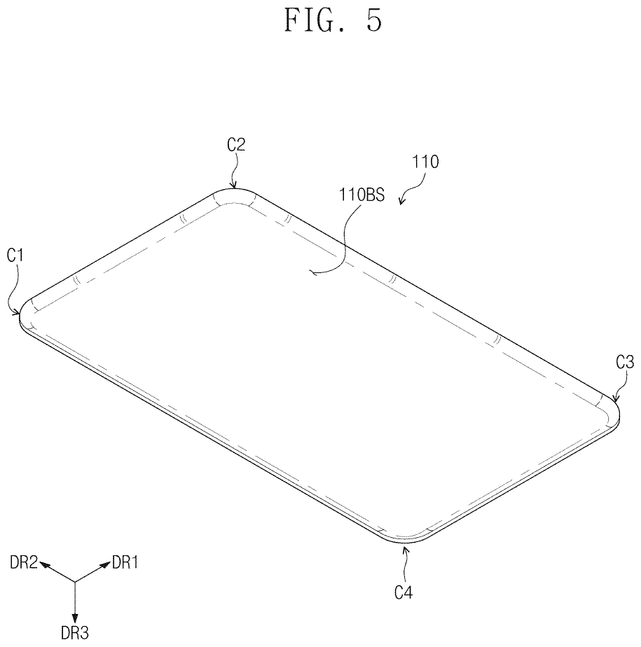

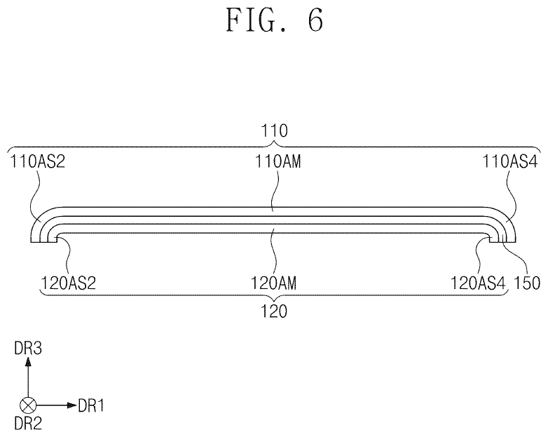

FIG. 3 is a perspective view of an embodiment of a display device of the disclosure. FIG. 4 is an exploded perspective view illustrating an embodiment of a partial configuration of the display device according to the disclosure. FIG. 5 is a perspective view of an embodiment of a window according to the disclosure. FIG. 6 is a perspective view of an embodiment of the window according to the disclosure.

Referring to FIGS. 3 and 4, a display device 100 may be a device that is activated by an electrical signal and displays an image. In an embodiment, the display device 100 may include a device such as a monitor, a mobile phone, a tablet personal computer, a navigation device, and a game console, for example. However, an embodiment of the display device 100 is as one of the embodiments and is not limited to an embodiment as long as the embodiment does not deviate from the concept of the disclosure. In an embodiment, the display device 100 illustrates, as one of the embodiments, a mobile phone.

A display area may be defined in the display device 100. The display device 100 may display an image through the display area and receive an external input. The display area may include a main display area 100AM and a first sub-display area 100AS1, a second sub-display area 100AS2, a third sub-display area 100AS3, and a fourth sub-display area 100AS4.

The main display area 100AM may be substantially parallel to a plane defined by a first direction DR1 and a second direction DR2. However, the disclosure is not limited thereto, and unlike the illustration, the main display area 100AM may have a shape that is concavely or convexly curved with respect to the plane defined by the first direction DR1 and the second direction DR2.

The main display area 100AM may display an image in a third direction DR3 intersecting the first direction DR1 and the second direction DR2. The third direction DR3 may be defined as a thickness direction of the display device 100. Front surfaces (or upper surfaces) and rear surfaces (or lower surfaces) of members constituting the display device 100 may be opposite to each other in the third direction DR3.

In the specification, the wording “in a plan view” may be defined as a state of being viewed in the third direction DR3. In the specification, the wording “in a cross-section” may be defined as a state of being viewed in the first direction DR1 or the second direction DR2. Directions indicated by the first direction DR1, the second direction DR2, and the third direction DR3 are relative concepts and may be changed to other directions.

The main display area 100AM may have a quadrangular shape, e.g., rectangular shape having short sides extending in the first direction DR1 and long sides extending in the second direction DR2. However, the disclosure is not limited thereto, and the main display area 100AM may have various shapes such as a circular shape or a polygonal shape in a plan view.

Each of the first sub-display area 100AS1, the second sub-display area 100AS2, the third sub-display area 100AS3, and the fourth sub-display area 100AS4 may be bent from the main display area 100AM and may have a predetermined curvature. The first sub-display area 100AS1, the second sub-display area 100AS2, the third sub-display area 100AS3, and the fourth sub-display area 100AS4 may have the same curvature. However, the disclosure is not limited thereto, and at least some of the first sub-display area 100AS1, the second sub-display area 100AS2, the third sub-display area 100AS3, and the fourth sub-display area 100AS4 may have different curvatures.

The main display area 100AM, the first sub-display area 100AS1, the second sub-display area 100AS2, the third sub-display area 100AS3, and the fourth sub-display area 100AS4 may be next (adjacent) to each other to implement a continuous display area. The first sub-display area 100AS1 and the third sub-display area 100AS3 may extend from the long sides of the main display area 100AM parallel to the second direction DR2, and the second sub-display area 100AS2 and the fourth sub-display area 100AS4 may extend from the short sides of the main display area 100AM parallel to the first direction DR1.

The first sub-display area 100AS1 and the third sub-display area 100AS3 may extend in the first direction DR1 and may be spaced apart from each other in the second direction DR2 with the main display area 100AM interposed therebetween. The second sub-display area 100AS2 and the fourth sub-display area 100AS4 may extend in the second direction DR2 and may be spaced apart from each other in the first direction DR1 with the main display area 100AM interposed therebetween.

It is described in FIG. 3 that the display device 100 includes the main display area 100AM, the first sub-display area 100AS1, the second sub-display area 100AS2, the third sub-display area 100AS3, and the fourth sub-display area 100AS4, but the disclosure is not limited thereto. In an embodiment, the display device 100 may include only one (singular) main display area 100AM and some of the first sub-display area 100AS1, the second sub-display area 100AS2, the third sub-display area 100AS3, and the fourth sub-display area 100AS4, for example.

Referring to FIG. 4, the display device 100 may include a window 110, a display panel 120, a driving chip 130, and a main circuit board 140.

The window 110 may include an optically transparent insulating material, and the window 110 may include glass or plastic. The window 110 may have a multi-layer structure or a single-layer structure.

Referring to FIGS. 4 and 5, the window 110 may include a main transmissive surface 110AM, a first side transmissive surface 110AS1, a second side transmissive surface 110AS2, a third side transmissive surface 110AS3, and a fourth side transmissive surface 110AS4 which are bent and extend from the main transmissive surface 110AM, a first display corner part C1, a second display corner part C2, a third display corner part C3, and a fourth display corner part C4, and a bottom surface 110BS.

Each of the first side transmissive surface 110AS1, the second side transmissive surface 110AS2, the third side transmissive surface 110AS3, and the fourth side transmissive surface 110AS4 may have a predetermined curvature. The first side transmissive surface 110AS1, the second side transmissive surface 110AS2, the third side transmissive surface 110AS3, and the fourth side transmissive surface 110AS4 may have the same curvature or different curvatures. However, the disclosure is not limited thereto, and the first side transmissive surface 110AS1, the second side transmissive surface 110AS2, the third side transmissive surface 110AS3, and the fourth side transmissive surface 110AS4 may be planar.

The first side transmissive surface 110AS1 and the third side transmissive surface 110AS3 may extend in the first direction DR1 and may be spaced apart from each other in the second direction DR2 with the main transmissive surface 110AM interposed therebetween. The second side transmissive surface 110AS2 and the fourth side transmissive surface 110AS4 may extend in the second direction DR2 and may be spaced apart from each other in the first direction DR1 with the main transmissive surface 110AM interposed therebetween.

The first display corner part C1, the second display corner part C2, the third display corner part C3, and the fourth display corner part C4 may be arranged between the first side transmissive surface 110AS1, the second side transmissive surface 110AS2, the third side transmissive surface 110AS3, and the fourth side transmissive surface 110AS4. The first display corner part C1, the second display corner part C2, the third display corner part C3, and the fourth display corner part C4 may be connected to the first side transmissive surface 110AS1, the second side transmissive surface 110AS2, the third side transmissive surface 110AS3, and the fourth side transmissive surface 110AS4 to surround the main transmissive surface 110AM.

The first display corner part C1 may be a part that is disposed between the second side transmissive surface 110AS2 and the third side transmissive surface 110AS3, connects the second side transmissive surface 110AS2 and the third side transmissive surface 110AS3 extending in intersecting directions, and has a curvature. The second display corner part C2 may be a part that is disposed between the third side transmissive surface 110AS3 and the fourth side transmissive surface 110AS4, connects the third side transmissive surface 110AS3 and the fourth side transmissive surface 110AS4 extending in intersecting directions, and has a curvature. The third display corner part C3 may be a part that is disposed between the first side transmissive surface 110AS1 and the fourth side transmissive surface 110AS4, connects the first side transmissive surface 110AS1 and the fourth side transmissive surface 110AS4 extending in intersecting directions, and has a curvature. The fourth display corner part C4 may be a part that is disposed between the first side transmissive surface 110AS1 and the second side transmissive surface 110AS2, connects the first side transmissive surface 110AS1 and the second side transmissive surface 110AS2 extending in intersecting directions, and has a curvature.

The first display corner part C1, the second display corner part C2, the third display corner part C3, and the fourth display corner part C4 may correspond to corners of the display device 100, respectively. The first display corner part C1, the second display corner part C2, the third display corner part C3, and the fourth display corner part C4 may have a curvature, and thus the corners of the display device 100 may have a rounded shape without being angled.

The display panel 120 may be disposed under the window 110 and attached to the window 110. The display panel 120 in an embodiment of the disclosure may be a light emitting display panel. In an embodiment, the display panel 120 may be an organic light emitting display panel or an inorganic light emitting display panel, for example. A light emitting layer of the organic light emitting display panel may include an organic light emitting material. A light emitting layer of the inorganic light emitting display panel may include a quantum dot or a quantum rod.

The display panel 120 may include a first portion 121 and a second portion 122. The first portion 121 and the second portion 122 may be next (adjacent) to each other in the second direction DR2. The second portion 122 may protrude and extend from the first portion 121 in the second direction DR2, and the first portion 121 and the second portion 122 may have a continuous shape (or an integral shape). A width WT1 of the first portion 121 in the first direction DR1 may be greater than a width WT2 of the second portion 122 in the first direction DR1. Thus, a length of a boundary 120BD between the first portion 121 and the second portion 122 may be smaller than the width WT1 of the first portion 121.

The first portion 121 of the display panel 120 may include a main display area 120AM, and a first side display area 120AS1, a second side display area 120AS2, a third side display area 120AS3, and a fourth side display area 120AS4. The main display area 120AM, and the first side display area 120AS1, the second side display area 120AS2, the third side display area 120AS3, and the fourth side display area 120AS4 may provide an image toward the window 110. Although not illustrated, the display panel 120 may further define a non-display area surrounding the main display area 120AM, and the first side display area 120AS1, the second side display area 120AS2, the third side display area 120AS3, and the fourth side display area 120AS4.

The window 110 may be attached to the first portion 121 of the display panel 120. That is, the first portion 121 may be attached to the main transmissive surface 110AM, and the first side transmissive surface 110AS1, the second side transmissive surface 110AS2, the third side transmissive surface 110AS3, and the fourth side transmissive surface 110AS4. In an embodiment, the main display area 120AM may be attached to the main transmissive surface 110AM, and the first side display area 120AS1, the second side display area 120AS2, the third side display area 120AS3, and the fourth side display area 120AS4 may be attached to the first side transmissive surface 110AS1, the second side transmissive surface 110AS2, the third side transmissive surface 110AS3, and the fourth side transmissive surface 110AS4, respectively, for example.

The second portion 122 not attached to the window 110 may be bent toward a rear surface of the first portion 121. The driving chip 130 may be disposed (e.g., mounted) on the second portion 122, and the main circuit board 140 may be attached to the second portion 122. The driving chip 130 may be a chip-type timing control circuit. However, this is illustrative, and the driving chip 130 may be disposed (e.g., mounted) on a film separate from the display panel 120. In this case, the driving chip 130 may be electrically connected to the display panel 120 through the film.

FIG. 6 illustrates a state in which the window 110 and the display panel 120 are attached by an adhesive layer 150. The adhesive layer 150 may include a general adhesive or a pressure sensitive adhesive. In an embodiment, the adhesive layer 150 may be a transparent adhesive member such as a pressure sensitive adhesive film (“PSA”), an optically clear adhesive film (“OCA”), or an optically clear adhesive resin (“OCR”), for example.

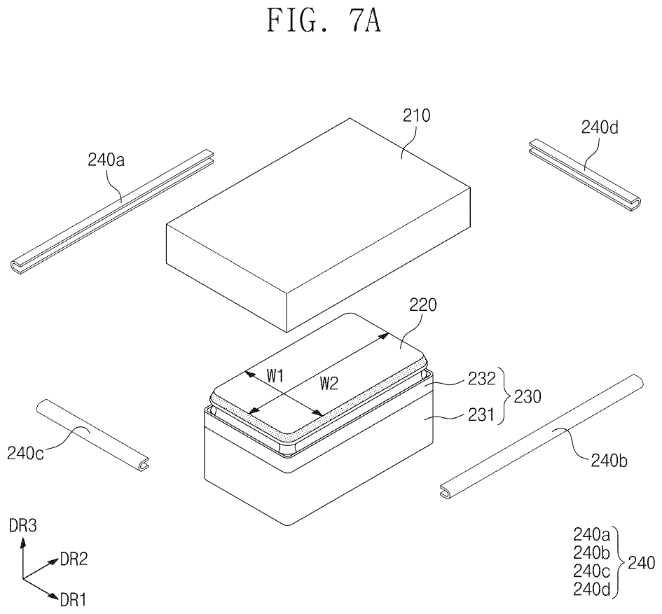

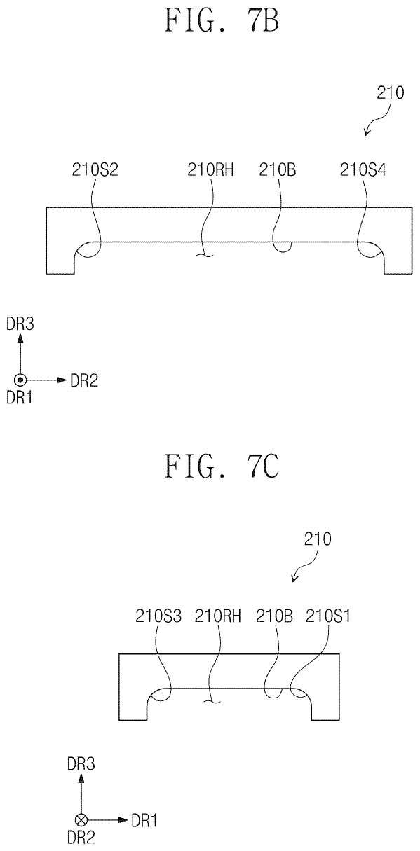

FIG. 7A is a perspective view of an embodiment of electronic device manufacturing equipment of the disclosure. FIGS. 7B and 7C are cross-sectional views of an embodiment of a configuration of the electronic device manufacturing equipment of the disclosure.

Referring to FIG. 7A, electronic device manufacturing equipment according to the disclosure may include an upper jig 210, a pad 220, a lower jig 230, and a clamp 240. The electronic device manufacturing equipment may be equipment used in a lamination process of coupling the window 110 (refer to FIG. 4) and the display panel 120 (refer to FIG. 4) to a window and a display panel.

The upper jig 210 may be disposed on the pad 220 to provide the window 110. The window 110 may be disposed and provided on a seating surface of the upper jig 210. An upper surface of the window 110 may be formed in a shape corresponding to the seating surface of the upper jig 210. In a lamination operation, the seating surface of the upper jig 210 may support and press the upper surface of the window 110. FIGS. 7B and 7C are cross-sectional views illustrating the upper jig 210.

Referring to FIGS. 7B and 7C, the upper jig 210 may include a bottom surface 210B, and a first side surface 210S1, a second side surface 210S2, a third side surface 210S3, and a fourth side surface 210S4 that are bent and extend from the bottom surface 210B. In the seating surface of the upper jig 210, an accommodation groove 210RH may be defined by the bottom surface 210B and the first side surface 210S1, the second side surface 210S2, the third side surface 210S3, and the fourth side surface 210S4. The window 110 (refer to FIG. 4) may be fixed to the accommodation groove 210RH. The upper surface of the window 110 may be formed to include a curved surface in a cross-section by the bottom surface 210B and the first side surface 210S1, the second side surface 210S2, the third side surface 210S3, and the fourth side surface 210S4.

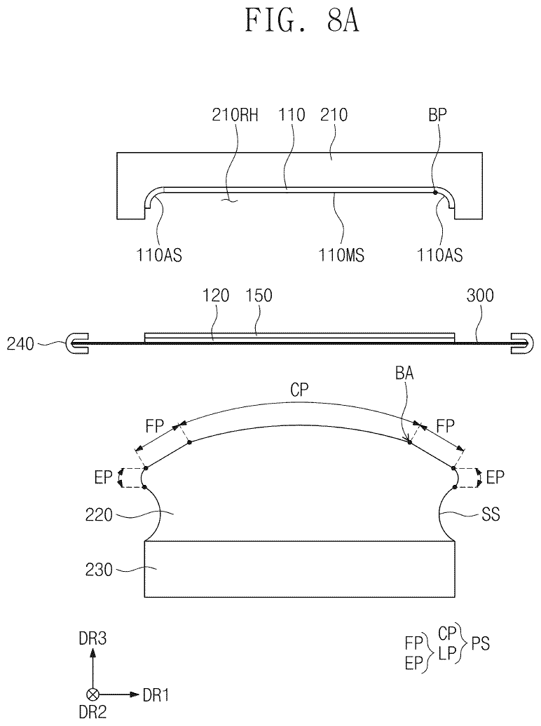

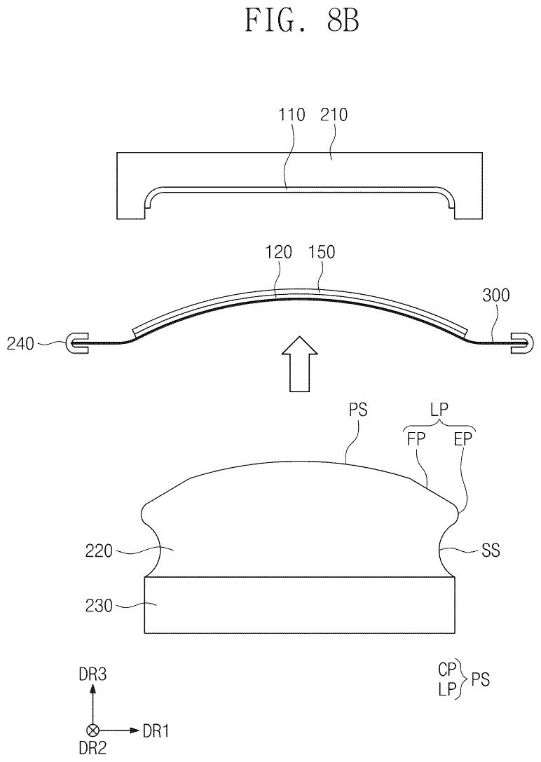

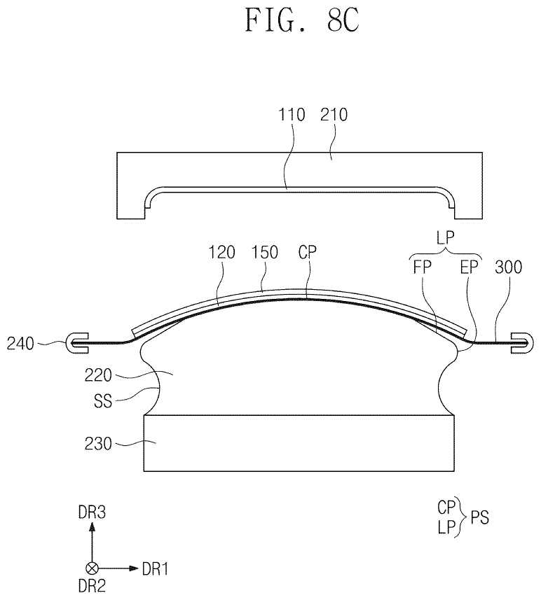

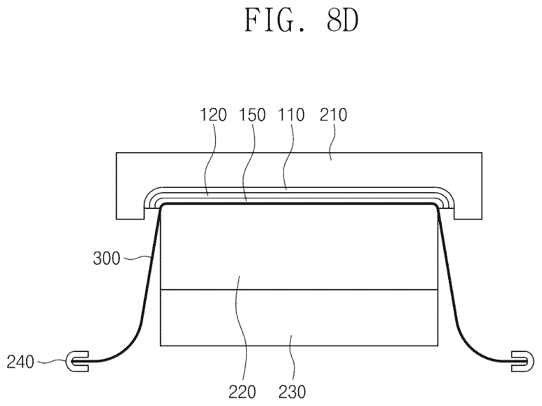

Referring back to FIG. 7A, the pad 220 may be disposed between the upper jig 210 and the lower jig 230. The pad 220 may press a lower side of the display panel 120. A pressing surface PS (refer to FIG. 8A) of the pad 220 may include an upper surface and a corner, and the corner may include two short sides having a first length W1 in the first direction DR1 and two long sides having a second length W2 in the second direction DR2. Details of a shape of the pad 220 will be provided below.

The pad 220 may be accommodated in the lower jig 230. In this case, a portion of the pad 220 may be accommodated in the lower jig 230, a remaining (the other) portion thereof may be exposed to the outside of the lower jig 230, and accordingly, a rear surface of the pad 220 may contact the lower jig 230.

The pad 220 may be elastic. The pad 220 may include a material of which a shape is easily deformed by pressure, and the disclosure is not particularly limited. In an embodiment, the pad 220 may include silicone rubber, for example. The pad 220 that presses a lower side of the display panel 120 is elastic, and thus when the window 110 is attached, the display panel 120 may be prevented from being damaged.

The lower jig 230 may be disposed under the pad 220 to support the pad 220. The lower jig 230 may include a base portion 231 and a case portion 232. The case portion 232 may accommodate the pad 220. In this case, at least a portion of the pad 220 may be exposed to the outside of the case portion 232. The base portion 231 may be disposed under the case portion 232 to support the case portion 232. Although not illustrated, the electronic device manufacturing equipment may further include a backlight disposed inside the base portion 231. The backlight may provide an illumination light for identifying alignment between the display panel 120 and the window 110 in a process of laminating the display panel 120 and the window 110. Accordingly, it is possible to easily identify the alignment between the display panel 120 and the window 110 and improve accuracy.

The lower jig 230 may move the pad 220 toward the upper jig 210 or in a direction away from the upper jig 210. In an embodiment, the lower jig 230 and the pad 220 may be moved in a direction parallel to the third direction DR3, for example.

The clamps 240 may be arranged to be next (adjacent) to four corners of the pad 220. A first clamp 240a and a second clamp 240b may be spaced apart from each other in the first direction DR1 with the pad 220 interposed therebetween and may be arranged on long sides of the pad 220. A third clamp 240c and a fourth clamp 240d may be spaced apart from each other in the second direction DR2 with the pad 220 interposed therebetween and may be arranged on short sides of the pad 220.

The clamps 240 may clamp a guide film 300 (refer to FIG. 8A) to which a rear surface of the display panel 120 (refer to a lower surface of the display panel 120 in FIG. 4) is attached in a process of laminating the window 110 and the display panel 120 (refer to FIG. 4), which will be described below. In an embodiment, the clamps 240 may be fitting portions in which predetermined grooves are defined, for example. That is, the guide film 300 may be inserted into the corresponding groove and thus stably fixed. Each of the clamps 240 may be fixed to a support. The clamp 240 may rotate and move counterclockwise with respect to the support. Accordingly, the guide film 300 may be pulled and bent by the movement of the clamp 240.

FIGS. 8A to 8D are cross-sectional views illustrating an embodiment of some of operations of a method of manufacturing an electronic device using the electronic device manufacturing equipment according to the disclosure. FIGS. 8A to 8D illustrate an operation of laminating the display panel and the window using the electronic device manufacturing equipment described with reference to FIGS. 7A to 7C.

Referring to FIG. 8A, the window 110 may be fixed to the upper jig 210. The window 110 may be seated in the accommodation groove 210RH of the upper jig 210. As described above, the seating surface of the upper jig 210 may have a shape corresponding to the shape of the upper surface of the window 110.

The display panel 120 may be provided in a state of being coupled to the guide film 300 and the adhesive layer 150. The guide film 300 may cover a rear surface of the display panel 120, and the adhesive layer 150 may cover an upper surface of the display panel 120. However, the disclosure is not limited thereto. In an embodiment, the adhesive layer 150 may be provided on a lower surface of the window 110, for example. Both the guide film 300 and the adhesive layer 150 may be attached to the first portion 121 (refer to FIG. 4) of the display panel 120. A planar area of the guide film 300 may be larger than a planar area of the first portion 121 of the display panel 120.

The display panel 120 may be provided and fixed between the pad 220 and the upper jig 210 by the clamps 240. In an embodiment, the clamps 240 may clamp the guide film 300, for example. That is, the display panel 120 may not be directly fixed to the clamps 240 but may be indirectly fixed to the clamps 240 through the guide film 300. Thus, damage caused by a clamping operation of the clamps 240 may not be generated in the display panel 120.

The pad 220 may be provided under the window 110 and the display panel 120. The pad 220 may include the pressing surface PS, a rear surface BS, and a side pad surface SS connecting the pressing surface PS and the rear surface BS.

The pressing surface PS of the pad 220 may include a curved portion CP and a connection portion LP. The curved portion CP may have a curvature in a cross-section. In a process of laminating the display panel 120 and the window 110, the curved portion CP may be closer to the display panel 120 and the adhesive layer 150 than the connection portion LP. The curved portion CP may be aligned to overlap a main transmissive surface 110 MS of the window 110.

The connection portion LP may have a curvature in a cross-section. The connection portion LP may be connected to the curved portion CP and the side pad surface SS. The connection portion LP may define a corner of the pressing surface PS. The connection portion LP may include an edge portion EP and a flat portion FP.

The edge portion EP may have a predetermined curvature in a cross-section. The flat portion FP may include a flat surface in a cross-section. The flat portion FP may connect the curved portion CP and the edge portion EP.

The flat portion FP may be aligned to overlap the side transmissive surface 110AS of the window 110. A boundary BA between the flat portion FP and the curved portion CP may overlap the main transmissive surface 110 MS of the window 110 and may not overlap the side transmissive surface 110AS of the window 110. In more detail, a starting point of the flat portion FP next (adjacent) to the curved portion CP may be aligned at a position closer to a center of the window 110 than a bending starting point BP of the window 110.

Referring to FIGS. 8B and 8C, the pad 220 and the lower jig 230 may move in a direction (or in the third direction DR3) toward the display panel 120. In this process, the guide film 300 may contact the pad 220, and the pad 220 may press the display panel 120 and the adhesive layer 150 in the third direction DR3 via the guide film 300. Accordingly, the display panel 120 and the window 110 may be compressed. The shapes of the guide film 300, the display panel 120, and the adhesive layer 150 may be modified to correspond to the shape of the pad 220.

Referring to FIGS. 8C and 8D, an operation of compressing the display panel 120 and the window 110 by applying pressure to the pad 220 may include a first compressing operation of compressing portions of the window 110 and the display panel 120 by applying pressure to the curved portion CP and a second compressing operation of compressing other portions of the window 110 and the display panel 120 by applying pressure to the pressing surface PS except for the curved portion CP. That is, an area in which pressure is applied to the display panel 120 by the pad 220 in the second compressing operation may be different from an area pressed in the first compressing operation.

Referring to FIG. 8C, in the first compressing operation, the flat portion FP of the pad 220 may not contact the display panel 120 and may not contact the guide film 300 disposed on the rear surface of the display panel 120. Accordingly, a pressure applied to the pad 220 may not be sufficiently transmitted to a bending area of the window 110 at a position aligned with the flat portion FP of the pad 220, and thus compressing with the display panel 120 may not be performed.

Referring to FIG. 8D, in the second compressing operation, the pressing surface PS of the pad 220 except for the curved portion CP may contact the guide film 300 disposed on the rear surface of the display panel 120, and accordingly, the window 110 and the display panel 120 may be finally coupled.

According to the disclosure, as an area having a plane is formed on the pressing surface PS of the pad 220, the area may be compressed against the display panel 120 sequentially from a central area to a bending area of the window 110, pressure is uniformly transmitted, and thus a bubble inflow phenomenon and defects such as cracks that may occur during the compressing process may be prevented.

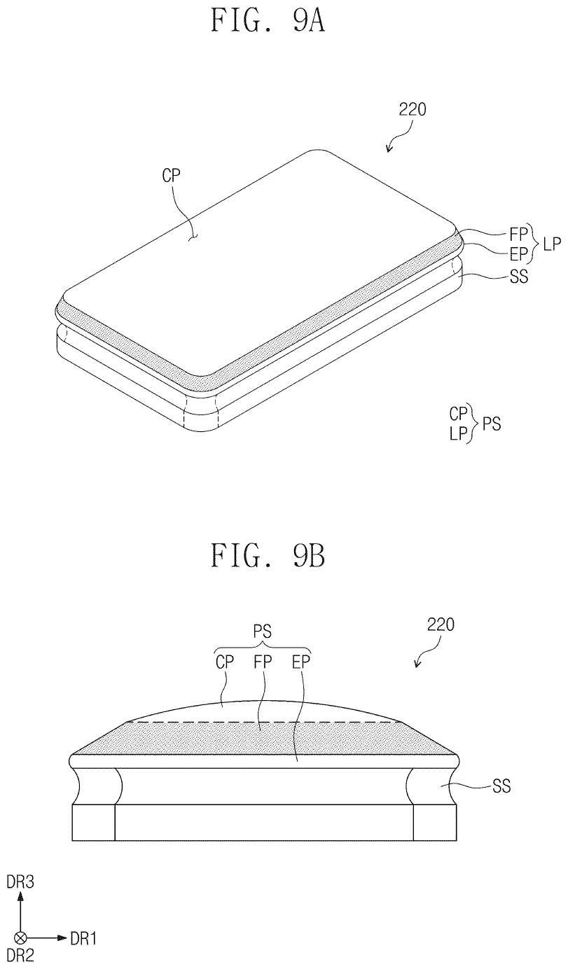

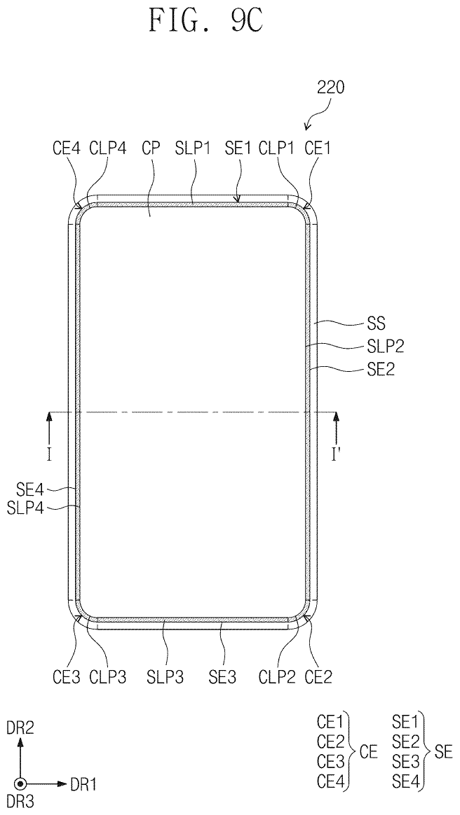

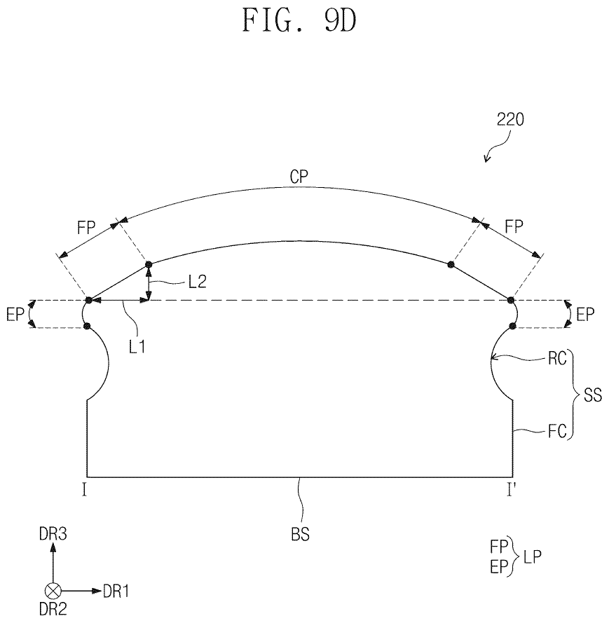

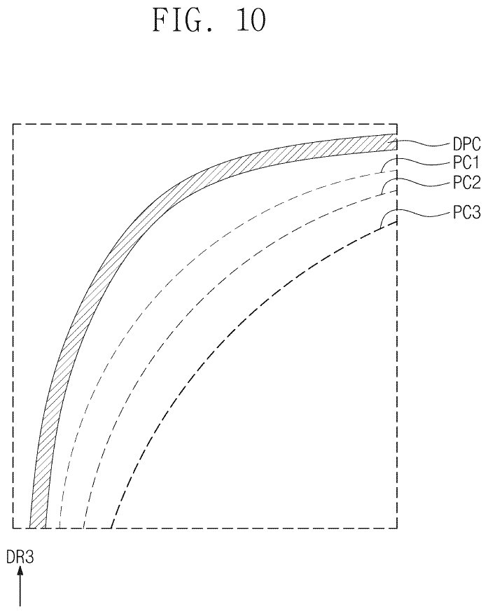

FIGS. 9A and 9B are perspective views of an embodiment of an embodiment of a pad of the disclosure. FIG. 9C is a plan view of the pad according to the disclosure. FIG. 9D is a cross-sectional view of an embodiment of the pad of the electronic device manufacturing equipment according to the disclosure. FIG. 10 is a schematic view illustrating a shape of a corner portion of each of the pads having different radii of curvature and a shape of a corner portion of a display panel.

Referring to FIGS. 9A to 9D, the pad 220 may include the pressing surface PS, the rear surface BS, and the side pad surfaces SS connecting the pressing surface PS and the rear surface BS.

The pressing surface PS may include the curved portion CP and the plurality of connection portions LP connecting the curved portion CP and the side pad surfaces SS.

The curved portion CP may have a curvature in a cross-section and may include a convex curved surface. Accordingly, a center of curvature of the curved portion CP may be disposed inside the pad 220. In an embodiment, a radius of curvature of the curved portion CP may be in a range of 300 millimeters (mm) to 2,000 mm, for example. However, the radius of curvature of the curved portion CP is not necessarily limited to this range and is not limited to a predetermined value as long as the curved portion CP has a curvature.

Each of the connection portions LP may include the edge portions EP and the flat portions FP connecting the curved portion CP and the edge portions EP.

Each of the edge portions EP may have a predetermined curvature in a cross-section and may include a convex curved surface. Accordingly, a center of curvature of the edge portion EP may be disposed inside the pad 220. In an embodiment, a radius of curvature of each of the edge portions EP in a cross-section may be in a range of 0.5 mm to 3 mm, for example. However, the radius of curvature of the edge portions EP is not limited thereto and may deviate from this range under predetermined conditions. Further, the curvature of each of the edge portions EP may be different from the curvature of the curved portion CP. In an embodiment, the radius of curvature of each of the edge portions EP may be smaller than the radius of curvature of the curved portion CP, for example. As the radius of curvature of the edge portion EP becomes smaller, pressure applied by the pad 220 becomes greater, and thus when the display panel 120 and the window 110 are compressed, a bubble occurrence phenomenon in the corner portions C1, C2, C3, and C4 (refer to FIG. 4) of the window 110 may be reduced.

The flat portions FP may connect the curved portion CP to the edge portions EP. Each of the flat portions FP may have a flat surface. The flat surface may be an inclined surface inclined with respect to the rear surface BS. In an embodiment, a horizontal length L1 (hereinafter, also referred to as a horizontal length) of the inclined surface in a cross-section may be in a range of 2 mm to 6 mm, and a vertical length L2 (hereinafter, also referred to as a height) of the inclined surface in a cross-section may be in a range of 0.5 mm to 3 mm, for example. However, the horizontal length L1 and the height L2 of the inclined surface are not necessarily limited to this range and may be set to other values as long as the height of the inclined surface is smaller than the radius of curvature of the edge portion EP.

Referring to FIG. 9D, each of the side pad surfaces SS may include a curved surface RC having a curvature in a cross-section and a portion FC having a flat surface in a cross-section. In this case, the portion FC having the flat surface may correspond to a side surface of the pad 220 accommodated in the case portion 232 (refer to FIG. 7A) of the lower jig 230. The curved surface RC may be concave. Accordingly, a center of curvature of the side pad surface SS may be disposed outside the pad 220. In this case, the curved surface RC may be connected to the edge portion EP. Further, a radius of curvature of the curved surface RC may be in a range of 1 mm to 4 mm. However, the radius of curvature is not limited thereto and may deviate from this range according to design conditions. As the side pad surface SS includes a form recessed toward a central portion of the pad 220, when pressure is applied to the pad 220 to compress the display panel 120 and the window 110, pressure transmitted to the connection portion LP and the pressing surface PS is reduced, and thus deformation of a corner of the pad 220 may be minimized, and unnecessary spreading may be prevented.

Referring back to FIG. 9B, the pressing surface PS may have corners including four straight sides SE1, SE2, SE3, and SE4 and four corner sides CE1, CE2, CE3, and CE4 in a plan view. The four corner sides CE may be arranged between the straight sides SE to connect the straight sides SE next to each other. A corner of the pressing surface PS may be defined by the connection portions LP.

The connection portions LP may include straight connection portions SLP1, SLP2, SLP3, and SLP4 and corner connection portions CLP1, CLP2, CLP3, and CLP4. Sides of the straight connection portions SLP1, SLP2, SLP3, and SLP4 may define the straight sides SE of the pressing surface PS. Sides of the corner connection portions CLP1, CLP2, CLP3, and CLP4 may define the corner sides CE of the pressing surface PS. A curvature of each of the corner connection portions CLP1, CLP2, CLP3, and CLP4 in a plan view may be smaller than a curvature of the edge portion EP connecting the flat portion FP and the side pad surface SS in a cross-section.

FIG. 10 illustrates shapes of pad corner portions PC1, PC2, and PC3 of each of the pads having different radii of curvature and a shape of a corner portion DPC of the display panel 120. In the specification, the corner portion may mean a curved area of the corner of the pad 220 or the display panel 120 in a plan view.

A radius of curvature of the first pad corner portion PC1 may be relatively smaller than radii of curvature of the second pad corner portion PC2 and the third pad corner portion PC3. In this case, the pad 220 may be first in contact with an outer area of the display panel 120 other than a central area of the corner portion DPC. Therefore, an initial contact area between the display panel 120 and the pad 220 is limited, and thus a possibility that stress is concentrated at a predetermined contact point increases. As a result, a crack may occur in the display panel 120, thereby degrading reliability.

A radius of curvature of the third pad corner portion PC3 may be relatively greater than radii of curvature of the first pad corner portion PC1 and the second pad corner portion PC2. In this case, a curved surface of the corner portion of the pad 220 may be gently formed, and accordingly, a contact area with the display panel 120 may be reduced. Accordingly, the pad 220 may not be sufficiently in close contact with the display panel 120, relatively small pressure may be generated in a compressing process, and thus adhesion between the pad 220 and the display panel 120 may be degraded. As a result, the pad 220 and the display panel 120 may not be uniformly in contact with each other, thus cracks may occur in the display panel 120, and reliability may be degraded.

In the case of the second pad corner portion PC2, unlike the first pad corner portion PC1 and the third pad corner portion PC3, contact may be made in a state in which a corner portion of the pad 220 is balanced with a corner portion of the display panel 120. In detail, a radius of curvature of the second pad corner portion PC2 may be in a range of 6 mm to 12 mm. In this case, a contact area between the pad 220 and the display panel 120 may be properly secured, pressure distribution may be kept uniform, and thus concentration of stress at a predetermined portion may be alleviated. Accordingly, deformation of the pad 220 may be minimized, cracks may be prevented from being generated during a lamination process, and adhesion stability between the pad 220 and the display panel 120 may be improved. Accordingly, process reliability may be improved.

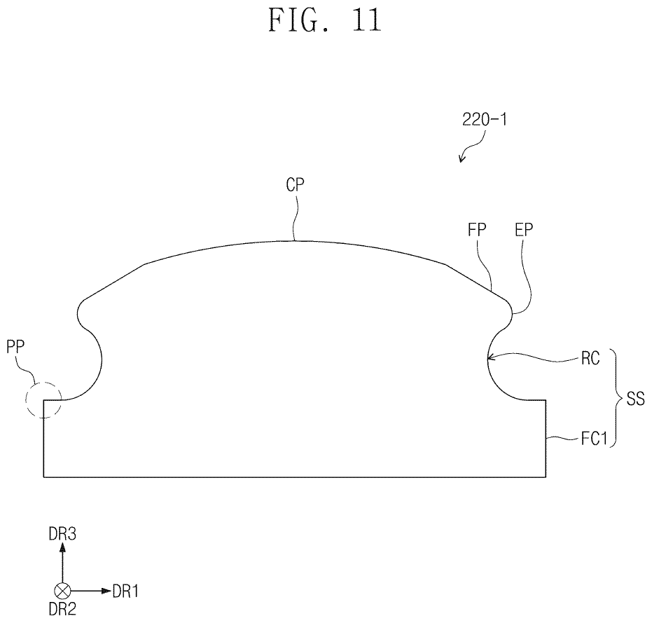

FIG. 11 is a cross-sectional view of an embodiment of the pad of the disclosure. In description with reference to FIG. 11, the same/similar reference numerals are used for the same/similar components as those described in FIGS. 7A to 10, and duplicated descriptions thereof will be omitted.

Referring to FIG. 11, the side pad surface SS may include a portion PP protruding from the edge portions EP in a cross-section. In this way, when a side surface of the pad 220 has a shape protruding from the edge portion EP, a pad 220-1 may be more stably supported inside the case portion 232 (refer to FIG. 7A), and a phenomenon in which the pad 220-1 is easily deformed or pushed during a compressing process may be prevented. Further, pressure distribution may be kept uniform while the protruding portion PP of the pad 220-1 contacts the case portion 232, and thus the concentration of stress at a predetermined portion may be alleviated. Accordingly, deformation of the pad 220-1 may be minimized, and the adhesion stability between the pad 220 and the display panel 120 may be improved. In an embodiment, the pad 220-1 may include a curved surface RC and a portion FC-1 having a flat surface in a cross-section.

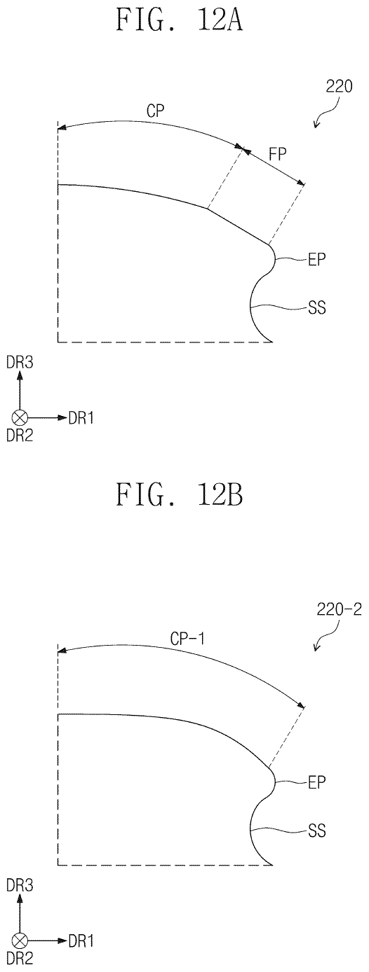

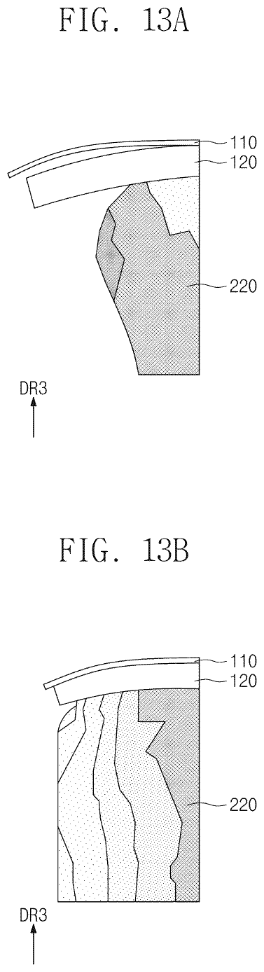

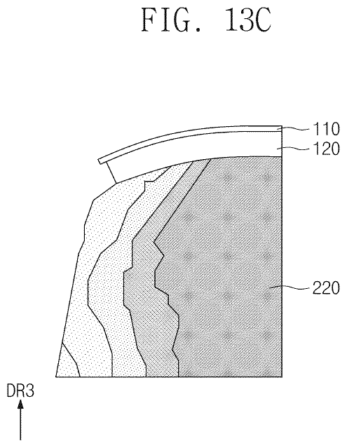

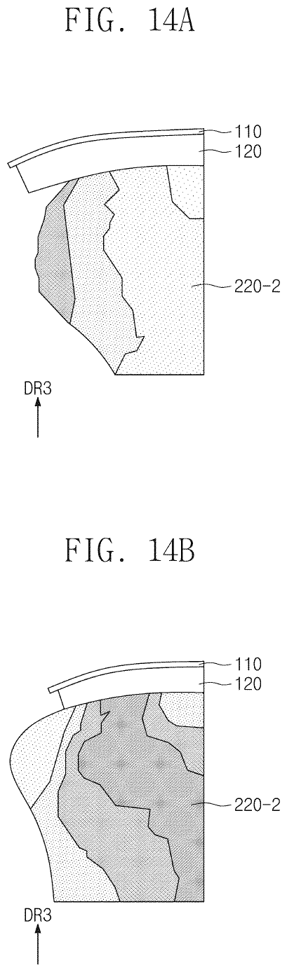

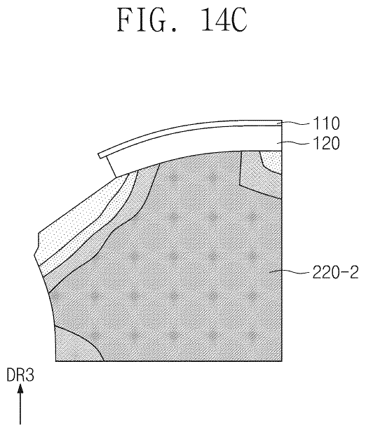

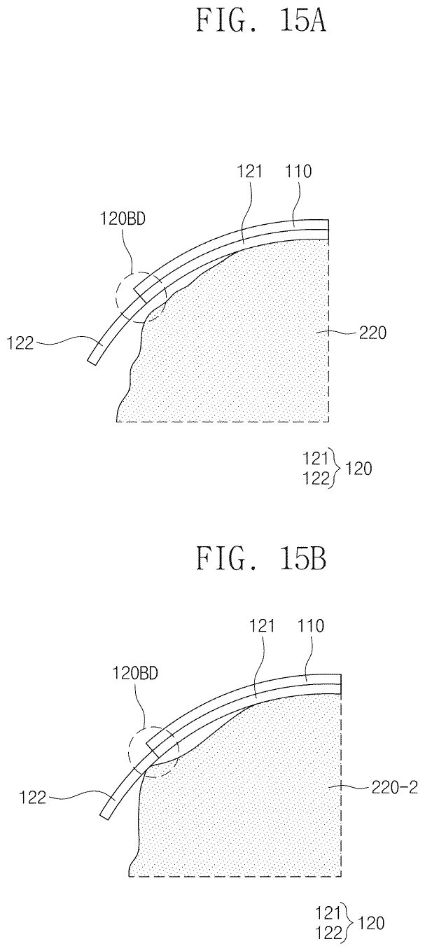

FIG. 12A is an enlarged cross-sectional view of an embodiment of a partial area of the pad of the disclosure. FIG. 12B is an enlarged cross-sectional view of an embodiment of the partial area of the pad according to the disclosure. FIGS. 13A to 13C are schematic views illustrating an embodiment of a deformed state of the pad in a process of compressing the display panel and the window using the pad according to the disclosure. FIGS. 14A to 14C are schematic views illustrating an embodiment of a deformed state of the pad in a process of compressing the display panel and the window using the pad according to the disclosure. FIG. 15A is a schematic view illustrating an embodiment of a deformed state of the pad in a lamination process of the display panel and the window. FIG. 15B is a schematic view illustrating an embodiment of a deformed state of the pad in a lamination process of the display panel and the window.

FIGS. 13A to 13C and 14A to 14C illustrate a deformed state of a pad at a portion next (adjacent) to a bending area of a window. In detail, a process of deforming the pad 220 in stages as the pad 220 is pressed is illustrated. Further, in FIGS. 13A to 13C and 14A to 14C, as a shade displayed on the pad 220 becomes darker, an intensity of applied pressure becomes greater.

Referring to FIGS. 12A and 13A to 13C, in an embodiment of the disclosure, as described above, the pressing surface PS of the pad 220 may include the curved portion CP, the edge portion EP, and the flat portion FP connecting the edge portion EP. When pressure is applied to the pad 220 to compress the display panel 120 and the window 110, the curved portion CP disposed at an uppermost portion of the pad 220 may be preferentially disposed toward the display panel 120, and accordingly, the central area of the window 110 may be compressed. In this case, the flat portion FP of the pad 220 may not contact the display panel 120, the pressure applied to the pad 220 may not be sufficiently transmitted to the bending area of the window 110 aligned with the flat portion FP of the pad 220, and thus the display panel 120 may not be compressed. Thereafter, a portion corresponding to the flat portion FP of the pad 220 before deformation may be pressed to face a portion of the display panel 120, and in this case, as the corresponding portion of the display panel 120 reaches the bending area of the window 110, the display panel 120 and the window 110 may be compressed

Referring to FIGS. 12B and 14A to 14C, the pressing surface PS of a pad 220-2 may not include the flat portion FP disposed between the curved portion CP-1 and the edge portion EP. That is, the pressing surface PS may have a curvature in the entirety of the area. When pressure is applied to the pad 220-2 not including the flat portion FP to compress the display panel 120 and the window 110, the curved portion CP-1 of the pad 220-2 may simultaneously face the central area and the bending area of the window 110, and accordingly, the display panel 120 may be compressed. However, in this case, the pressing surface PS of the pad 220-2 may simultaneously compress the central area and the bending area of the window 110, making it difficult to perform the compressing sequentially from an inside. Accordingly, excessive pressure may be applied to a predetermined area, sufficient pressure may not be transmitted to another area, and thus an unadhesive empty space may be defined. Further, when the bending area of the window 110 is not uniformly supported, cracks may occur due to local stress concentration, and as air bubbles are introduced due to the formed empty space, internal defects may occur.

FIGS. 15A and 15B illustrate deformed states of the pad 220 at the boundary 120BD between the first portion 121 (refer to FIG. 4) and the second portion 122 (refer to FIG. 4) of the display panel. FIG. 15A illustrates a deformed state in a compressing process using the pad 220 of FIG. 12A, and FIG. 15B illustrates a deformed state in a compressing process using the pad 220 of FIG. 11B.

Referring to FIG. 15A, the pad 220 may be disposed not to be contact with the boundary 120BD between the first portion 121 and the second portion 122 of the display panel 120. That is, as the pad 220 is not in contact with an area next (adjacent) to the main circuit board 140 (refer to FIG. 4), pressure applied around the corresponding boundary 120BD may be relatively decreased. Accordingly, the risk of crack or damage may be reduced, and the display panel 120 and the window 110 may be more uniformly compressed.

Referring to FIG. 15B, the pad 220-2 may be contact with the boundary 120BD between the first portion 121 and the second portion 122 of the display panel 120. That is, as the pad 220-2 contacts an area next (adjacent) to the main circuit board 140, pressure applied around the corresponding boundary 120BD may be relatively increased. Accordingly, the risk of cracks in the display panel 120 may be increased due to local stress concentration.

According to the disclosure, the pad 220-2 may contact the display panel 120 sequentially from the central area to the bending area of the window 110, the pressure may be more uniformly transmitted from the pad 220-2 to the display panel 120 and the window 110, and thus defects such as a bubble inflow phenomenon and cracks that may occur in a lamination process may be prevented. Further, as the pad 220-2 is disposed not to contact an area next (adjacent) to a circuit board, unnecessary pressure may be prevented from being applied to an area in which the circuit board is disposed. Accordingly, an electronic device in which the risk of damage to the circuit board is reduced and reliability is improved may be provided.

According to the disclosure, an electronic device having improved compression precision by compressing a display panel and a window using a pad having a pressing surface including a flat surface on a surface may be provided.

In particular, the display panel and the window may be pressed sequentially from central areas to bending areas thereof, and thus uniform pressing may be achieved without generation of relatively small pressure.

Although the description has been made above with reference to an embodiment of the disclosure, it may be understood that those skilled in the art or those having ordinary knowledge in the art may variously modify and change the disclosure without departing from the spirit and technical scope of the disclosure described in the appended claims. Thus, the technical scope of the disclosure is not limited to the detailed description of the specification but should be defined by the appended claims.

What is claimed is:

1. An electronic device manufacturing equipment comprising:
an upper jig including a bottom surface and an accommodation groove defined by side surfaces bent and extending from the bottom surface;
a lower jig disposed below the upper jig; and
a pad disposed between the upper jig and the lower jig, the pad including:
a pressing surface facing the bottom surface, the pressing surface including:
a curved portion having a predetermined curvature in a cross-section;
edge portions; and
flat portions respectively connecting the curved portion and the edge portions and each including a flat surface;
a rear surface facing the lower jig; and
side pad surfaces bent from the rear surface toward the pressing surface, and
wherein the edge portions are respectively connected to the side pad surfaces.

2. The electronic device manufacturing equipment of claim 1, wherein each of the edge portions has a predetermined curvature in the cross-section, and the predetermined curvature of the curved portion and the predetermined curvature of each of the edge portions are different from each other.

3. The electronic device manufacturing equipment of claim 2, wherein a radius of curvature of each of the edge portions is smaller than a radius of curvature of the curved portion.

4. The electronic device manufacturing equipment of claim 2, wherein the flat surface is an inclined surface inclined with respect to the rear surface.

5. The electronic device manufacturing equipment of claim 4, wherein a height of the inclined surface in the cross-section is smaller than a radius of curvature of each of the edge portions.

6. The electronic device manufacturing equipment of claim 1, wherein each of the side pad surfaces includes a curved surface having a predetermined curvature in the cross-section.

7. The electronic device manufacturing equipment of claim 6, wherein the curved surface is a concave surface.

8. The electronic device manufacturing equipment of claim 6, wherein the curved surface is connected to the edge portions.

9. The electronic device manufacturing equipment of claim 1, wherein each of the side pad surfaces includes a portion protruding from the edge portions in the cross-section.

10. The electronic device manufacturing equipment of claim 1, wherein the pressing surface includes a corner having a predetermined curvature in a plan view.

11. The electronic device manufacturing equipment of claim 1, wherein the pad is elastic.

12. An electronic device manufacturing equipment comprising:
an upper jig including a bottom surface and an accommodation groove defined by side surfaces bent and extending from the bottom surface;
a lower jig disposed below the upper jig; and
a pad disposed between the upper jig and the lower jig, the pad including:
a pressing surface including corners including four straight sides and four corner sides arranged between the four straight sides and each connecting straight sides next to each other in a plan view among the four straight sides, the pressing surface including:
a curved portion including a convex curved surface toward the upper jig; and
a plurality of connection portions; each of the plurality of connection portions including:
a flat surface; and
a curved surface;
a rear surface; and
a plurality of side pad surfaces each connecting the pressing surface and the rear surface,
wherein the plurality of connection portions connects the curved portion and the plurality of side pad surfaces and defines the corners, and
wherein the curved surface connects the flat surface and the plurality of side pad surfaces.

13. The electronic device manufacturing equipment of claim 12, wherein the plurality of connection portions includes straight connection portions defining the four straight sides and corner connection portions defining the four corner sides, and
wherein a curvature of each of the corner connection portions in the plan view is smaller than a curvature of the curved surface in a cross-section.

14. The electronic device manufacturing equipment of claim 12, wherein the flat surface has an inclination with respect to the bottom surface in a cross-section, and
wherein a height of the inclination is smaller than a radius of curvature of the curved surface.

15. The electronic device manufacturing equipment of claim 12, wherein a side pad surface of the plurality of connection portions includes a concave surface.

16. The electronic device manufacturing equipment of claim 13, wherein a curvature of a curved surface of each of the straight connection portions in the cross-section is greater than a curvature of the curved portion.

17. A method of manufacturing an electronic device, the method comprising:
fixing a window including a main transmissive surface and side transmissive surfaces bent and extending from the main transmissive surface in one direction to an upper jig including an accommodation groove;
fixing a display panel including a rear surface to which a guide film is attached to a clamp;
providing a pad below the window and the display panel, the pad including a pressing surface, a rear surface, and side pad surfaces connecting the rear surface and the pressing surface; and
compressing the bent display panel and the window by applying pressure to the pad in a direction toward the display panel,
wherein the pressing surface includes a curved portion having a predetermined curvature in a cross-section, edge portions respectively connected to the side pad surfaces, and flat portions connecting the curved portion and the edge portions and each including a flat surface, and
wherein, in the providing the pad below the window and the display panel, the flat portions are aligned to overlap the side transmissive surfaces, respectively.

18. The method of claim 17, wherein the compressing the display panel and the window includes:
compressing portions of the window and the display panel by applying pressure to the curved portion; and
compressing other portions of the window and the display panel by applying pressure to the pressing surface except for the curved portion.

19. The method of claim 18, wherein, in the compressing portions of the window and the display panel, the flat portions are not in contact with the guide film.
